(19) United States
(12) Patent Application Publication
(10) Pub. No.: US 2026/0299432 A1
(43) Pub. Date: Oct. 1, 2026

(54) INFORMATION PROCESSING APPARATUS, INFORMATION PROCESSING METHOD, LITHOGRAPHIC APPARATUS, AND METHOD OF MANUFACTURING ARTICLE

(71) Applicant: CANON KABUSHIKI KAISHA, Tokyo (JP)

(72) Inventor: KENTA KITA, Tochigi (JP)

(21) Appl. No.: 19/571,357

(22) Filed: Mar. 18, 2026

(30) Foreign Application Priority Data
Mar. 26, 2025 (JP) 2025-051248

(51) Int. Cl. G03F 7/00

(52) U.S. Cl. CPC G03F 7/70525

(57) ABSTRACT

An information processing apparatus comprises at least one processor and a memory coupled to the at least one processor. The memory stores instructions that, when executed by the at least one processor, cause the at least one processor to acquire processing results of a processing apparatus and generate a screen for selecting a first group and a second group used for judging an abnormality of the processing results on the basis of the acquired processing results together with a screen for displaying the processing results for each of a plurality of processing conditions.

### CROSS-REFERENCE TO RELATED APPLICATION

This application claims priority to Japanese Patent Application No. 2025-051248, which was filed on Mar. 26, 2025 and which is hereby incorporated by reference herein in its entirety.

### BACKGROUND

### Field of the Technology

The present disclosure relates to an information processing apparatus, an information processing method, a lithographic apparatus, a method of manufacturing an article, and the like.

### Description of the Related Art

In a semiconductor manufacturing factory, typically, semiconductor manufacturing apparatuses such as substrate processing apparatuses that process substrates are disposed, and it is required to efficiently process substrates after grasping the operating status of each apparatus. In addition, in a case in which an abnormality has occurred in a semiconductor manufacturing apparatus, it is necessary to take an immediate action and to immediately recognize in which lot or wafer the abnormality has occurred, whether there are differences for each recipe that is a processing condition, and the like.

According to Japanese Patent Application Laid-Open No. 2021-173915, by displaying data in units of lots and wafers, reduction of time required to determine whether a factor is attributable to either a lot or a wafer is achieved. In addition, according to Japanese Patent Application Laid-Open No. 2021-173914, by displaying data in a time series in a different area for each recipe that is a processing condition, reduction of time required to determine whether the factor is common to apparatuses or is specific to the recipe is achieved.

Here, it is known to perform abnormality judgment using techniques such as machine learning or anomaly detection. However, before applying machine learning or the like, it may be necessary to determine items to be judged as abnormalities, collect and analyze data, and develop and validate models, and thus advanced technical expertise and substantial effort and time may be required.

### SUMMARY

An information processing apparatus according to an embodiment of the present disclosure is an information processing apparatus that manages a processing apparatus that is a management target and includes at least one processor and a memory coupled to the at least one processor. The memory stores instructions that, when executed by the at least one processor, cause the at least one processor to acquire processing results of the processing apparatus and generate a screen for selecting a first group and a second group used for judging an abnormality of the processing results on the basis of the acquired processing results together with a screen for displaying the processing results for each of a plurality of processing conditions.

Further features of various embodiments of the present disclosure will become apparent from the following description of embodiments with reference to the attached drawings.

### BRIEF DESCRIPTION OF THE DRAWINGS

FIG. 1 is a diagram illustrating a configuration example of a product manufacturing system according to a first embodiment.

FIG. 2 is a diagram illustrating an example of an exposure apparatus as an example of a pattern forming apparatus.

FIG. 3 is a diagram illustrating an example of the hardware configuration of an information processing apparatus constituting a management apparatus illustrated in FIG. 1.

FIG. 4 is a diagram illustrating an example of the functional configuration of a CPU illustrated in FIG. 3.

FIG. 5 is a flowchart illustrating an example of a method of setting information for judging an abnormality in the management apparatus illustrated in FIG. 1.

FIG. 6 is a diagram illustrating an example of a graph in which processing results are displayed in a time series.

FIG. 7 is a diagram illustrating an example of a graph in which processing results are displayed in a time series for each processing condition.

FIG. 8 is a diagram illustrating an example of a state in which a range common to the processing conditions is set in a graph in which processing results are displayed in a time series for each processing condition.

FIG. 9 is a diagram illustrating an example of a state in which a range common to the processing conditions and individual ranges for respective processing conditions are set in a graph in which processing results are displayed in a time series for each processing condition.

FIG. 10 is a diagram illustrating an example of a setting state for judging an abnormality in a graph in which processing results are displayed in a time series for each processing condition.

FIG. 11 is a diagram illustrating an example of a graph in which processing results of a plurality of exposure apparatuses according to a second embodiment are displayed in a time series for each processing condition.

FIG. 12 is a diagram illustrating an example of a setting state for judging an abnormality in a graph in which processing results of an exposure apparatus according to the second embodiment are displayed in time series for each processing condition.

FIG. 13 is a diagram illustrating an example of a state in which, in a graph in which processing results of an exposure apparatus according to the second embodiment are displayed in a time series for each processing condition, a setting for using only this apparatus and normal and warning ranges are set in a range common to the processing conditions.

### DESCRIPTION OF THE EMBODIMENTS

Hereinafter, with reference to the accompanying drawings, various modes of the present disclosure will be described using example embodiments. In each diagram, the same reference signs are applied to the same members or elements, and duplicate descriptions will be omitted or simplified.

### First Embodiment

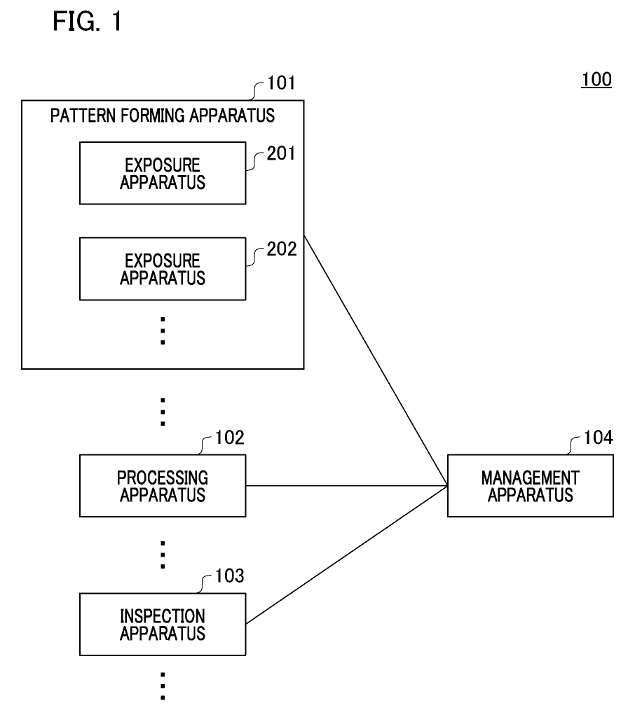

Hereinafter, a first embodiment is described below. In this embodiment, a product manufacturing system formed using a plurality of apparatuses and a management apparatus that manages the plurality of apparatuses is described. FIG. 1 is a diagram illustrating a configuration example of a product manufacturing system according to the present embodiment.

A product manufacturing system 100 illustrated in FIG. 1 is, for example, a system used for manufacturing semiconductors and includes a pattern forming apparatus 101 that forms patterns on a wafer (substrate), a processing apparatus 102, an inspection apparatus 103, and a management apparatus 104 that manages these apparatuses. In the product manufacturing system 100, one or more apparatuses are included in each of the pattern forming apparatus 101, the processing apparatus 102, and the inspection apparatus 103.

The pattern forming apparatus 101 may include exposure apparatuses 201 and 202 that emit light to a reticle (a mask, an original) on which a pattern is formed and project the pattern onto a shot region on a wafer using light from the reticle. The pattern forming apparatus 101 may also include, for example, an imprint apparatus that forms a composition in which the shape of a mold is transferred by bringing an imprint material supplied onto a wafer into contact with a mold (an original, a mold) and applying curing energy to the imprint material. The pattern forming apparatus 101 may further include a drawing apparatus that performs drawing on a substrate using a charged particle beam (an electron beam, an ion beam, or the like) through a charged particle optical system to form a pattern on the substrate. In other words, the pattern forming apparatus 101 is managed by the management apparatus 104 (an information processing apparatus) and corresponds to a lithography apparatus having a forming unit that forms a pattern for lithography.

The processing apparatus 102 may also include, for example, manufacturing apparatuses that perform predetermined processes other than processes performed by apparatuses such as the exposure apparatuses and the like in manufacturing articles, such as a coating apparatus that applies photosensitive media or the like onto a surface of a substrate, a developing apparatus that develops a substrate onto which a pattern has been transferred, and the like.

The inspection apparatus 103 may include, for example, an overlay inspection apparatus, a CD inspection apparatus, a pattern inspection apparatus, an electrical characteristic inspection apparatus, and the like. Here, the overlay inspection apparatus is an apparatus that inspects accuracy of positional deviation between an upper-layer pattern and a lower-layer pattern on a substrate on which patterns are formed on multiple layers. The CD inspection apparatus is an apparatus that inspects the accuracy of a dimension such as line width or the like of a pattern formed on a substrate. The pattern inspection apparatus is an apparatus that inspects the presence or absence of a pattern that does not satisfy an accuracy level due to foreign matter adhered to a substrate on which a pattern is formed, insufficient filling of an imprint material, or the like. The electrical characteristic inspection apparatus is an apparatus that inspects the accuracy of electrical characteristics of a semiconductor device or the like manufactured from a substrate on which a pattern is formed.

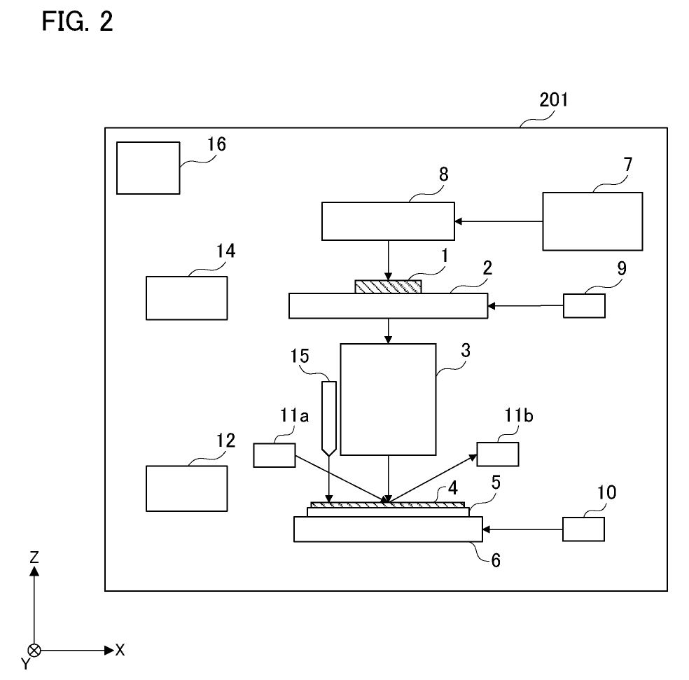

Next, as an example of the pattern forming apparatus 101, an exposure apparatus that exposes a wafer using light from a reticle on which a pattern is formed is described. FIG. 2 is a diagram illustrating an example of an exposure apparatus as an example of the pattern forming apparatus. The exposure apparatus 201 illustrated in FIG. 2 is described as a step-and-scan type exposure apparatus (scanner) that performs exposure while synchronously driving a reticle stage and a wafer stage. The exposure apparatus 201 is not limited to a scanner and may be a step-and-repeat type exposure apparatus (stepper) that performs exposure in a state in which the wafer stage is stationary.

The exposure apparatus 201 has a light source 7, an illumination optical system 8, a reticle stage 2, a projection optical system 3, a wafer stage 6, a wafer chuck 5, and a control unit 16. The exposure apparatus 201 further has a laser interferometer 9, a laser interferometer 10, a focus detection unit consisting of 11a and 11b, a wafer transfer unit 12, a reticle transfer unit 14, and an alignment scope 15. In FIG. 2, a direction parallel to the optical axis of the projection optical system 3 is defined as a Z-axis direction, and two directions orthogonal to each other in a plane perpendicular to the Z-axis direction are defined as an X-axis direction and a Y-axis direction.

Examples of the light source 7 include a high-pressure mercury lamp, an ArF excimer laser, a KrF excimer laser, and the like. The light source 7 is not necessarily disposed inside a chamber of the exposure apparatus 201 and may be configured to be externally attached. Light emitted from the light source 7 illuminates a reticle 1 (an original plate, a mask) through the illumination optical system 8. On the reticle 1, a pattern to be transferred onto a wafer 4 (substrate) coated with a photosensitive material is drawn, and the reticle 1 is mounted on the reticle stage 2. The reticle stage 2 holds the reticle by suction through a reticle chuck (not illustrated) and, for example, is configured to be movable by a linear motor (not illustrated).

The projection optical system 3 projects (exposes) an image of the pattern drawn on the reticle 1 onto the wafer 4 placed on the wafer chuck 5. When projecting the image of the pattern onto the wafer 4, an inverted and reduced image at a projection magnification (for example, 1/4) is projected onto the wafer 4 through the projection optical system 3. When an area onto which the pattern image is projected is represented as a shot region, a plurality of shot regions are set on the wafer 4, and projection onto the shot regions is repeatedly performed sequentially.

The wafer stage 6 is movable in the X direction and the Y direction by being driven by a linear motor (not illustrated). The wafer chuck 5 is mounted on the wafer stage 6 and holds the wafer 4. The wafer stage 6 positions the wafer chuck 5 in the Z direction, a θ direction, a ωX direction, and a ωY direction. Thus, the wafer 4 held by the wafer chuck 5 moves by driving the wafer stage 6 and the wafer chuck 5.

The laser interferometer 9 measures a position of the reticle stage 2 in the Y direction and also measures an attitude of the reticle stage 2. Similarly, the laser interferometer 9 includes a laser interferometer (not illustrated) for measuring a position of the reticle stage 2 in the X direction. The laser interferometer 10 measures a position of the wafer stage 6 on which the wafer 4 is mounted in the Y direction and also measures an attitude of the wafer stage 6. Similarly, the laser interferometer 10 includes a laser interferometer (not illustrated) for measuring a position of the wafer stage 6 in the X direction. The positions of the reticle stage 2 and the wafer stage 6 are controlled by the control unit 16 described below on the basis of positions measured by the laser interferometer 9 and the laser interferometer 10.

The focus detection unit include a light projecting system 11a that projects light (a plurality of beams) onto the wafer 4, a light receiving system 11b that receives reflected light from the wafer, and a detection unit (not illustrated) that detects light from the light receiving system and outputs a detection signal to the control unit 16. The light projecting system 11a and the light receiving system 11b are disposed to have a vicinity of an exit portion of the projection optical system 3 interposed therebetween, the light projecting system 11a emits obliquely incident light to the wafer, and the light receiving system 11b receives light reflected on an opposite side. From the detection signal detected by the focus sensor 11, the control unit 16 described below measures a position of the wafer 4 in the Z direction and controls movement of the wafer 4 according to the wafer stage 6.

The wafer transfer unit 12 transfers the wafer 4. The wafer transfer unit 12 transfers the wafer 4 from a wafer storage container (not illustrated) or the like that stores the wafer 4 to the wafer stage 6. In addition, the wafer transfer unit 12 transfers the wafer 4 from the wafer stage 6 to a wafer storage container or the like.

The reticle transfer unit 14 transfers the reticle 1. The reticle transfer unit 14 transfers the reticle 1 from a reticle storage container (not illustrated) or the like that stores the reticle 1 to the reticle stage 2. In addition, the reticle transfer unit 14 transfers the reticle 1 from the reticle stage 2 to a reticle storage container or the like.

The alignment scope 15 acquires a digital image signal acquired by imaging a mark formed on the wafer 4 in order to perform positioning (alignment) of the wafer 4 held by the wafer chuck 5. The alignment scope 15 includes an image sensor (not illustrated) that outputs a grayscale image signal corresponding to the brightness of reflected light from the wafer 4, that is, shading and an A/D converter (not illustrated) that converts the grayscale image signal acquired from the image sensor into a digital image signal. The control unit 16 described below detects a position of the mark formed on the wafer 4 using the acquired digital image signal and controls the wafer stage 6 on the basis of the detected position of the mark to position the wafer 4.

The control unit 16 controls the process of exposing the wafer 4 by controlling operations, adjustments, and the like of respective units of the exposure apparatus 201. The control unit 16 is an information processing apparatus that may be or include, for example, a Programmable Logic Device (PLD), such as a Field Programmable Gate Array (FPGA). Also, the control unit 16 may be an information processing apparatus that is or includes an Application Specific Integrated Circuit (ASIC) or a computer in which a program is installed. Also, the control unit 16 may be an information processing apparatus that includes a combination of all or a part of these. In addition, the control unit 16 may be or include a plurality of information processing apparatuses.

The control unit 16 may be configured integrally with other portions of the exposure apparatus 201 (within a common casing) or may be configured separately from other portions of the exposure apparatus 201 (within a separate casing). In addition, the control unit 16 controls execution of an exposure process (pattern forming process) of the wafer 4 by applying processing conditions acquired from a storage device or the like described below.

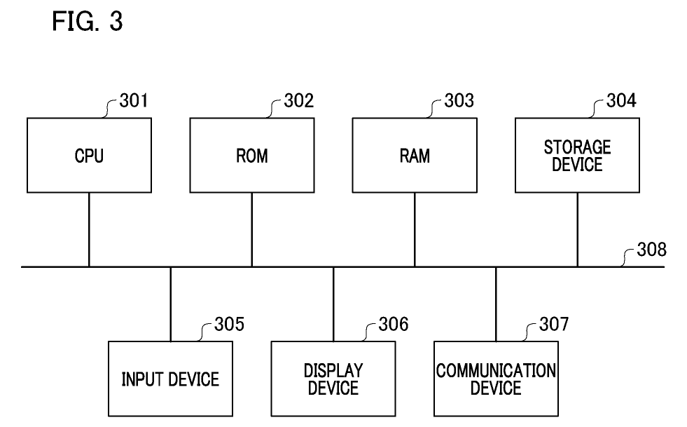

FIG. 3 is a diagram illustrating an example of the hardware configuration of an information processing apparatus. Each hardware configuration of the information processing apparatus functions in accordance with a program. In the example of FIG. 3, a CPU 301 is an arithmetic processing unit that performs arithmetic operations for control in accordance with a program and controls respective components connected to a bus 308. A ROM 302 is a read-only memory in which programs and data are stored. A RAM 303 is a memory for reading and writing data, and is used for storing programs and data. The RAM 303 is used for temporarily storing data, such as results of arithmetic operations performed by the CPU 301.

A storage device 304 is used for storing programs and data. The storage device 304 is also used as a temporary storage area for programs and data of an operating system (OS) of the information processing apparatus. Although input/output of data in the storage device 304 is slower than that in the RAM 303, the storage device 304 can store a large amount of data. The storage device 304 is preferably a non-volatile storage device capable of storing data as perpetual data such that the stored data can be referred to over a long period of time. The storage device 304 is mainly configured by a magnetic storage device (HDD) but may be a device that loads an external medium, such as a CD, a DVD, or a memory card, to read and write data.

An input device 305 is a device for inputting characters and data to the information processing apparatus, and various keyboards, mice, and the like correspond thereto. A display device 306 is a device for displaying information, processing results, and the like that are necessary for operations of the information processing apparatus, and a CRT, a liquid crystal monitor, and the like are examples thereof. A communication device 307 is used when the information processing apparatus is connected to a network to perform data communication using a communication protocol, such as TCP/IP, and to communicate with another information processing apparatus. In addition, the information processing apparatus may include a Graphics Processor Unit (GPU), which is not illustrated, to enable high-speed arithmetic processing.

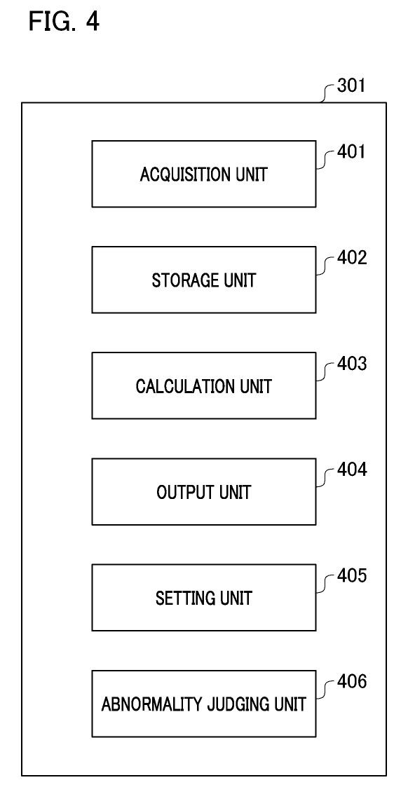

Next, the management apparatus 104 is described. As described above, the management apparatus 104 manages processing apparatuses such as the pattern forming apparatus 101 that are management targets. The management apparatus 104, for example, is configured by an information processing apparatus and may have a configuration identical or similar to that illustrated in FIG. 3. The management apparatus 104 is connected to a plurality of exposure apparatuses, for example, the exposure apparatus 201 and an exposure apparatus 202, through the communication device 307 for communication of data. FIG. 4 is a diagram illustrating an example of the functional configuration of the CPU 301 of the management apparatus 104. The CPU 301 of the management apparatus 104 can function as an acquisition unit 401, a storage unit 402, a calculation unit 403, an output unit 404, a setting unit 405, and an abnormality judging unit 406. Functions (operations) of respective units illustrated in FIG. 4 are described with reference to flowcharts and the like to be described below.

Next, a method of displaying processing results of the exposure apparatus 201 and setting information for judging an abnormality (information processing method) using the management apparatus 104 is described.

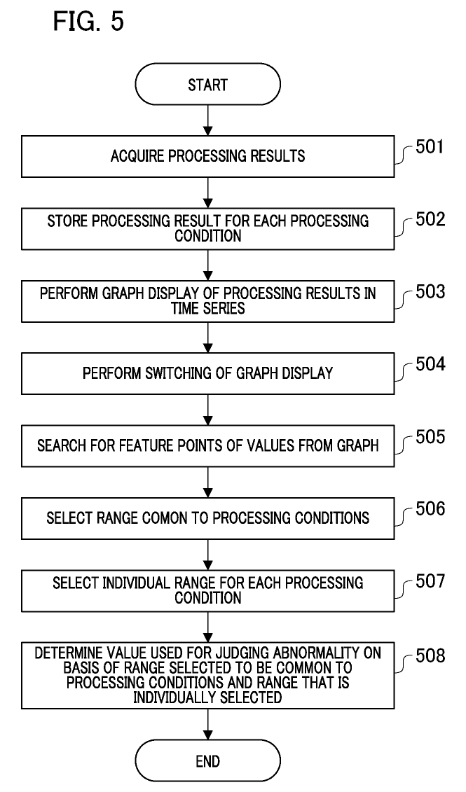

FIG. 5 is a flowchart illustrating an example of a method in which the management apparatus 104 displays processing results of the exposure apparatus 201 and sets information for judging an abnormality. First, in Step 501, the acquisition unit 401 acquires processing results from the exposure apparatus 201. Here, the processing results are data relating to an exposure process performed in the exposure apparatus 201.

In Step 502, the storage unit 402 stores the processing results acquired by the acquisition unit 401 in the storage device 304 for each processing condition. At this time, the calculation unit 403 performs statistical calculations, for example, for each lot, for each wafer (substrate), for each shot (pattern forming region), or for each mask (original plate), for example, on the basis of processing results for each processing condition accumulated in the storage unit 402 or the storage device 304. Examples of the statistical calculations include calculation of a maximum value, a minimum value, an average value, a median value, a standard deviation, and the like. The calculation unit 403 may also store calculated results in the storage unit 402 or the storage device 304. In other words, results statistically calculated by the calculation unit 403 are also included in the processing results.

In Step 503, the output unit 404 outputs the processing results stored in Step 502 to the display device 306 and displays the processing results in a time series on the display device 306. This display is, for example, a graph display as described below.

In Step 504, a user or the like operates the input device 305 to switch the graph display displayed in Step 504. For example, the display is switched from a state in which processing results are graphically displayed in a time series to a state in which processing results are graphically displayed in a time series for each processing condition.

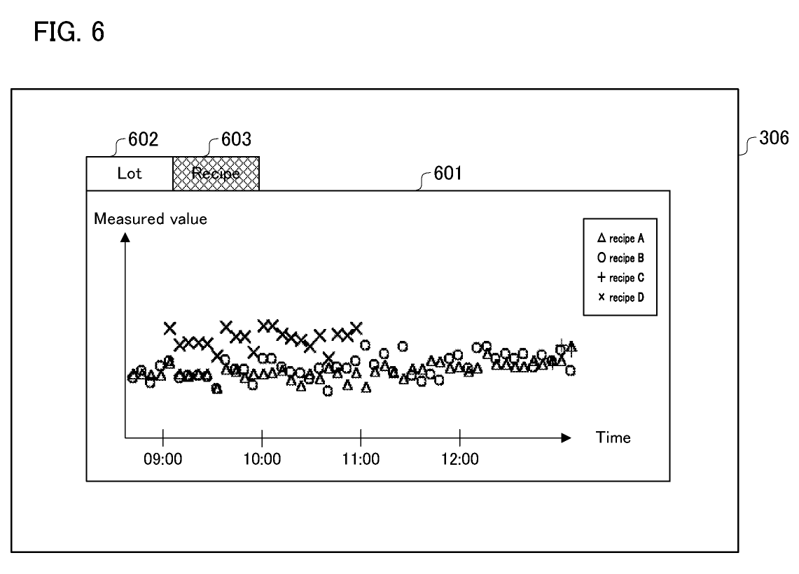

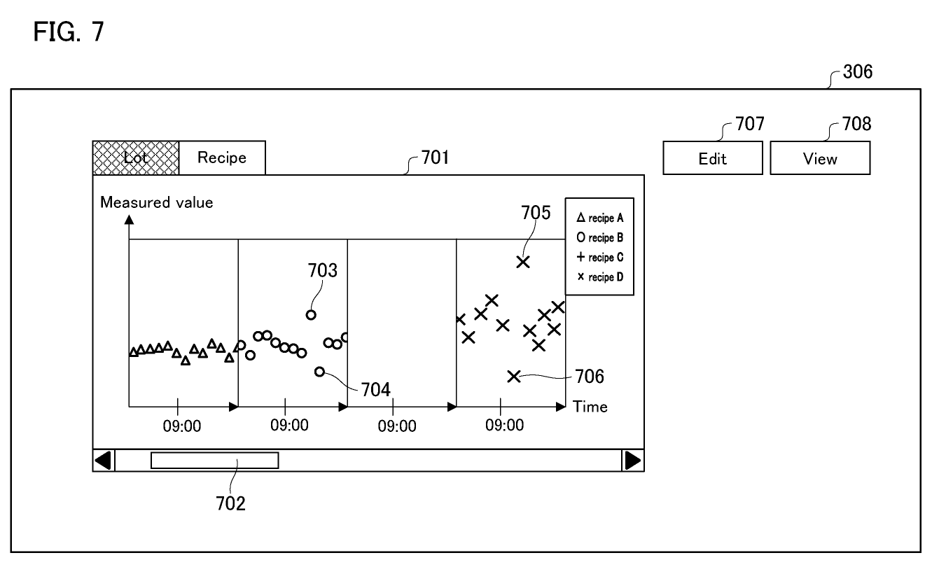

Details of a screen displayed by the display device 306 are described. FIG. 6 is a diagram illustrating an example of a screen in which processing results are graphically displayed in a time series. FIG. 7 is a diagram illustrating an example of a screen on which processing results are graphically displayed in a time series for each processing condition. In a graph 601 illustrated in FIG. 6, a horizontal axis represents a time at which processing is executed by the exposure apparatus 201, and a vertical axis represents processing results or statistical calculation results of the processing results. In a graph 701 illustrated in FIG. 7, a horizontal axis represents a time at which processing is executed by the exposure apparatus 201 for each processing condition after classification by each processing condition, and a vertical axis represents processing results or statistical calculation results similarly to the graph 601. In other words, the screen illustrated in FIG. 7 corresponds to a screen that displays processing results for each of a plurality of processing conditions on the basis of the processing results acquired by the acquisition unit 401.

A switching button 602 illustrated in FIG. 6 switches to a state in which the graph 601 is drawn in a display mode in which all the processing results are aligned in a time series. A switching button 603 illustrated in FIG. 6 is used to switch to a state in which the graph 701, in which processing results are aligned in a time series for each processing condition, is drawn. In the flowchart of FIG. 5, in Step 503, processing results are graphically displayed in a time series as illustrated in FIG. 6, and in Step 504, the display is switched to a state in which processing results are graphically displayed in a time series for each processing condition as illustrated in FIG. 7 in accordance with the switching button 603. In other words, the screens illustrated in FIGS. 6 and 7 can be switched between a mode in which a plurality of processing conditions are collectively displayed in a time series (FIG. 6) and a mode in which a plurality of processing conditions are displayed in a time series for each individual processing condition (FIG. 7).

A scroll bar 702 illustrated in FIG. 7 changes a display position of a graph in which a time direction is long because time series display is performed for each processing condition. An edit button 707 illustrated in FIG. 7 is used to edit settings for judging abnormalities. A display button 708 is used to display a setting state for judging a current abnormality in the graph 701 and processing results judged as abnormalities.

Returning to the description of FIG. 5, in Step 505, for example, feature points of values are searched from the graph of FIG. 7. From FIG. 7, it can be understood that recipe A and recipe B that are processing conditions have similar overall trends, and recipe D has a trend different from those of recipe A and recipe B. Furthermore, since processing results 703 and 704 of recipe B deviate from the overall trend, it can be understood that there is a possibility that an abnormality has occurred in the exposure apparatus 201 or a product. On the other hand, also in recipe D, since processing results 705 and 706 deviate from the overall trend of recipe D, it can be understood that there is a possibility that an abnormality has occurred in a product. For this reason, settings are performed such that processing results 703, 704, 705, and 706 are judged as abnormal.

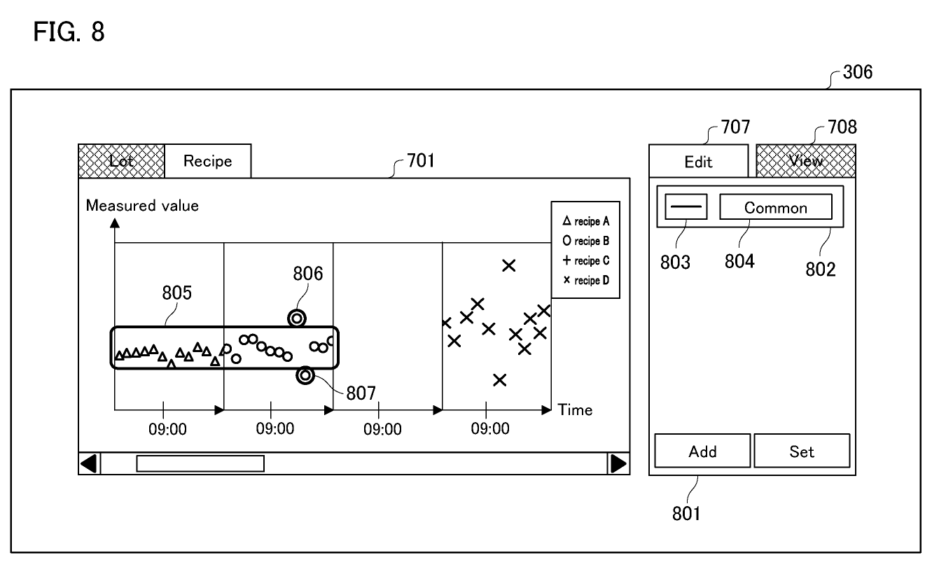

In Step 506, a common range is set in the processing conditions. The setting of a common range in processing conditions in Step 506 is described. FIG. 8 is a diagram illustrating an example of a state in which a common range is set in processing conditions in a graph in which processing results are displayed in a time series for each processing condition. When the edit button 707 is pressed, a range item list display 801 and an item (common range item) 802 indicating a range common to a plurality of processing conditions are displayed, and the display button 708 comes into an inactive state representing a state in which it has not been selected.

An item identifier 803 in the common range item 802 represents an identifier for identifying the common range item 802 on the graph. At this time, the item identifier 803 may be identified by color or by line thickness. An item type 804 in the common range item 802 represents a type of the item identifier 803. In FIG. 8, a common range (Common) is indicated. When the common range item 802 is selected, a state in which a range can be set for the graph 701 is formed. In that state, an arbitrary range is set for the graph 701 through an operation using a mouse that is one of the input devices 305. In FIG. 8, range 805 is set.

When the range is set as range 805, in order to identify which processing results are outside the range, processing results 806 and 807, for example, are displayed to be surrounded by the item identifier 803. In FIG. 8, the results are individually surrounded by thick lines as the item identifier 803. In other words, on a screen displaying processing results, processing results exceeding a threshold based on a first group and a threshold based on a second group are displayed with emphasis. Here, exceeding a threshold is not limited to being a value larger than the threshold but also includes being a value outside a range of an upper limit value and a lower limit value of the threshold.

The identifying method is not limited to a method using thick lines as illustrated in FIG. 8, and the expression may be changed in accordance with a method for representing the item identifier 803, and, in a case in which the identification is performed by color, the color may be changed darker. In a case in which a range selection state is desired to be cancelled, it may be performed by clicking outside the range of the graph 701, or canceling may be configured to be able to be performed by preparing a cancel button and pressing the cancel button in a state in which the item is selected. The set state is stored in the setting unit 405.

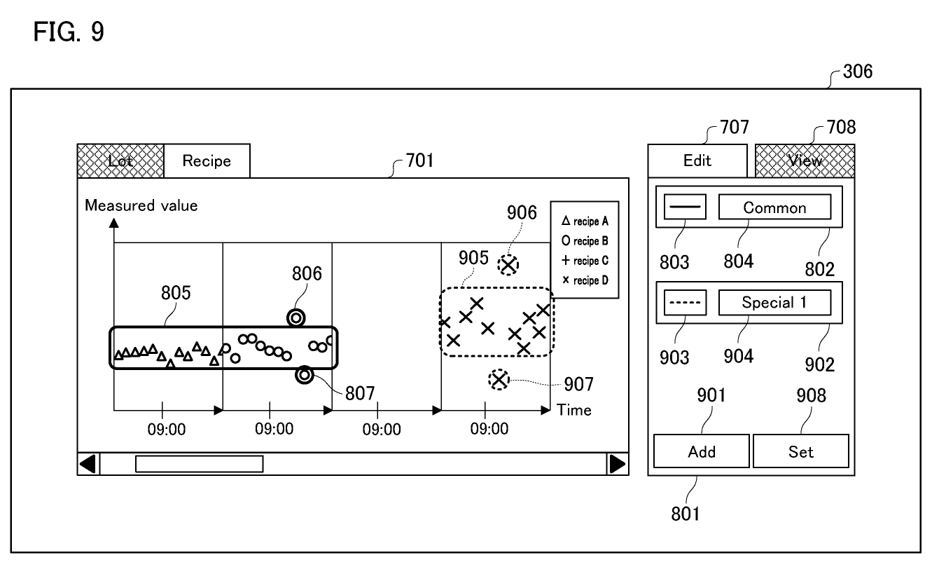

Returning to the description of FIG. 5, in Step 507, an individual range is set for each processing condition. FIG. 9 is a diagram illustrating an example of a state in which a common range that is common to processing conditions and an individual range for each processing condition are set in a graph in which processing results are displayed in a time series for each processing condition. An add button 901 is used to add a range item. A reflect button 908 is used to cause processing results outside a range set on the graph (outside a range of the upper limit value and the lower limit value) to be judged as an abnormality. When the add button 901 is pressed, an item (individual range item) 902 representing an individual range for each processing condition is added to the range item list display 801, and an item identifier 903 used for identifying the item on the graph and an item type 904 representing a type are displayed inside the individual range item 902. When the individual range item 902 is selected, a state in which a range can be set for the graph 701 is formed, and an arbitrary range is set through a mouse operation.

In FIG. 9, the range is set like range 905. When the range is set like range 905, as in the case of processing results 906 and 907, processing results outside the range can be identified, for example, by displaying them with being individually surrounded by the item identifier 903. In FIG. 8, they are individually surrounded by broken lines as the item identifier 903. The set state is stored in the setting unit 405. In accordance with this setting, for recipe D, the individual range item 902 becomes valid instead of the common range item 802.

For example, for recipe D, in a case in which only the setting of the common range item 802 is sufficient due to the trend being close to those of other recipes or the like, Step 507 may be omitted.

Then, in Step 508, values to be judged as abnormal are determined for ranges that are selected commonly and individually for the processing condition. In Step 508, when the reflect button 908 is pressed, on the basis of information of the range 805 and the range 905 set in the setting unit 405, a method for judging an abnormality using the calculation unit 403 is determined, and the method for judging an abnormality is stored in the storage device 304. The method for judging an abnormality includes an order of judging the range 805 and the range 905 to be described below and the like in addition to values (thresholds) for judging abnormalities. After storing the method for judging an abnormality, the range setting state of the graph 701 and the inactive state of the display button 708 are released.

In other words, the range 805 corresponds to a first group for judging an abnormality of processing results, and the range 905 corresponds to a second group for judging an abnormality of processing results. Accordingly, the output unit 404 that generates the screens illustrated in FIGS. 8 and 9 functions as a generation unit. Each of the first group and the second group may include at least one processing result. In the present embodiment, one or more processing results may be present in a portion surrounded by the range 805 or the range 905.

As a method for judging an abnormality, first, it is checked whether a processing result falls within the individual range 905 (within a range of the upper limit value and the lower limit value) for each processing condition, and in a case in which the processing condition does not correspond thereto, it is checked whether the processing result falls within the common range 805 (within a range of the upper limit value and the lower limit value). In a case in which there are a plurality of exposure apparatuses 201 that are management targets, the setting for judging an abnormality is simultaneously applied to the plurality of apparatuses. In accordance with this, the effort for individually setting each apparatus is eliminated. In other words, upper and lower ends of the range 805 and the range 905 in a vertical axis direction become thresholds for judging an abnormality. In the present embodiment, thresholds are set as a set of an upper limit value and a lower limit value. Accordingly, the first group and the second group have different thresholds for judging an abnormality.

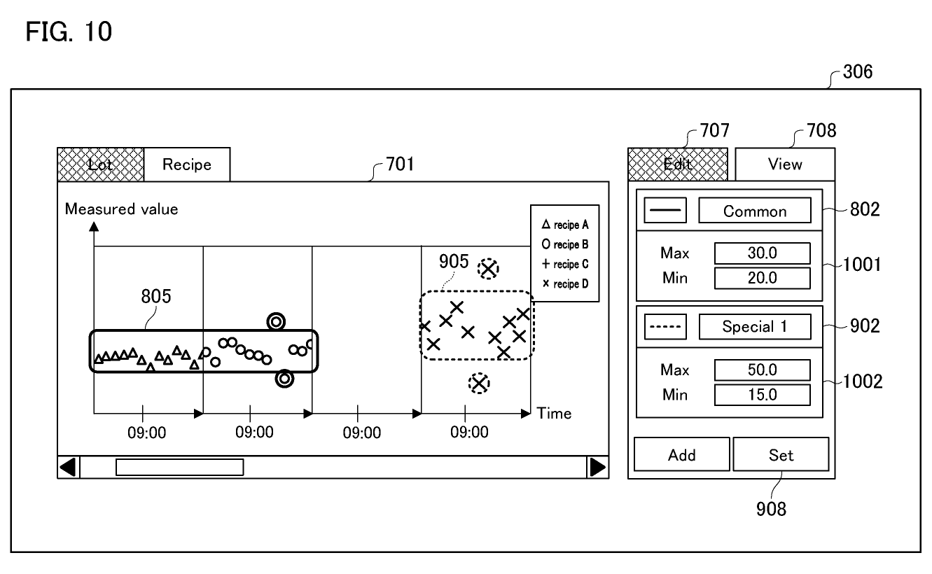

FIG. 10 is a diagram illustrating an example of a setting state for judging an abnormality on a graph in which processing results are displayed in a time series for each processing condition. A setting range 1001 represents a range 805 set as a common range item 802 as a numerical value. A setting range 1002 represents a range 905 set as an individual range item 902 as a numerical value. When a display button 708 is pressed, as illustrated in FIG. 10, the current setting state is displayed, and the set ranges can be checked numerically. In addition, the ranges 805 and 905 that have already been set are also displayed on a graph 701.

When an edit button 707 is pressed once in this state, the numerical values of the setting range 1001 and the setting range 1002 become editable, and editing can be performed using numerical values (the range 805 and the range 905 may be edited through a mouse operation). After modifying the ranges using numerical values or a mouse operation, the settings are reflected again by pressing the reflect button 908. In other words, the screen illustrated in FIG. 10 corresponds to a screen for displaying thresholds for judging an abnormality.

After applying the settings for judging an abnormality, measurement or exposure processing is performed by the exposure apparatus 201, and when processing results are stored in the storage unit 402, the abnormality judging unit 406 judges the processing results on the basis of the method for judging an abnormality. In addition, processing results that are regularly stored in the storage device 304 may be judged on the basis of the method for judging an abnormality. As a result of the judgment, in a case in which an abnormality is acquired, a pop-up may be displayed on the screen of the display device 306, or a notification may be provided through an e-mail, a chat, or the like. At this time, a screen on which the processing result judged as abnormal is displayed may be configured to be directly opened from a pop-up screen, an e-mail, a chat, or the like.

In other words, the abnormality judging unit 406 functions as a specifying unit that specifies an abnormality in processing results of the processing apparatus using the threshold based on the first group and the threshold based on the second group. In addition, the display device 306 functions as a display unit that displays the abnormality specified by the specifying unit.

Here, after applying the settings for judging an abnormality, for example, in a case in which processing results are obtained using a recipe (processing condition) other than the recipes A to D illustrated in FIGS. 7 and 8, the processing results are judged for abnormality on the basis of the setting of the common range 805. In other words, processing results acquired by the acquisition unit on the basis of a new processing condition after the first group and the second group are selected are handled as the first group. In addition, for new processing results of the recipes A to D, it is apparent that the recipes A to C are judged for abnormality on the basis of the setting of the common range 805, and the recipe D is judged for abnormality on the basis of the setting of the individual range 905.

According to the flowchart illustrated in FIG. 5, Step 501 functions as an acquisition step, and Steps 504 to 507 function as a generation step.

The management apparatus 104 according to the present embodiment has the acquisition unit 401 that acquires processing results of the exposure apparatuses 201 and 202 (processing apparatuses) and the output unit 404 that outputs information for displaying processing results for each of a plurality of processing conditions on the basis of the processing results acquired by the acquisition unit 401. The management apparatus 104 has the setting unit 405 (input unit) to which the first group and the second group selected for judging an abnormality of the processing results output by the output unit 404 are input. Furthermore, the management apparatus 104 has the abnormality judging unit 406 (specifying unit) that defines thresholds for judging an abnormality on the basis of the first group and the second group set in the setting unit 405 and specifies an abnormality in the processing results on the basis of the thresholds.

According to the present embodiment, a user can perform settings for judging an abnormality without requiring advanced technical skills or a large amount of effort and time.

Furthermore, information indicating that an abnormality has been judged can be passively acquired via a pop-up, an e-mail, a chat, or the like. Thus, the user can quickly become aware that some kind of abnormality has occurred in a management target apparatus.

Further, by referring to the screen of a detailed processing result from the information indicating that an abnormality has been judged, it is possible to visually understand whether the measurement or exposure processing result has become abnormal commonly across apparatuses or has become abnormal under an individual condition. Furthermore, since the settings can be applied to a plurality of apparatuses, information can be received and visually understood on a graph not for the set apparatus but for all management target apparatuses.

Accordingly, initial investigation can be performed quickly, the time required to eliminate an abnormality can be reduced, and an overall apparatus operation rate can be improved, which further leads to improved profitability.

### Second Embodiment

Next, an information processing apparatus according to a second embodiment is described. Description of the same configuration as that of the first embodiment is omitted, and hereinafter, differences from the first embodiment are focused in description.

In the present embodiment, a method for performing settings for judging an abnormality that is unique to an exposure apparatus 202 other than the exposure apparatus 201 set in the first embodiment is described.

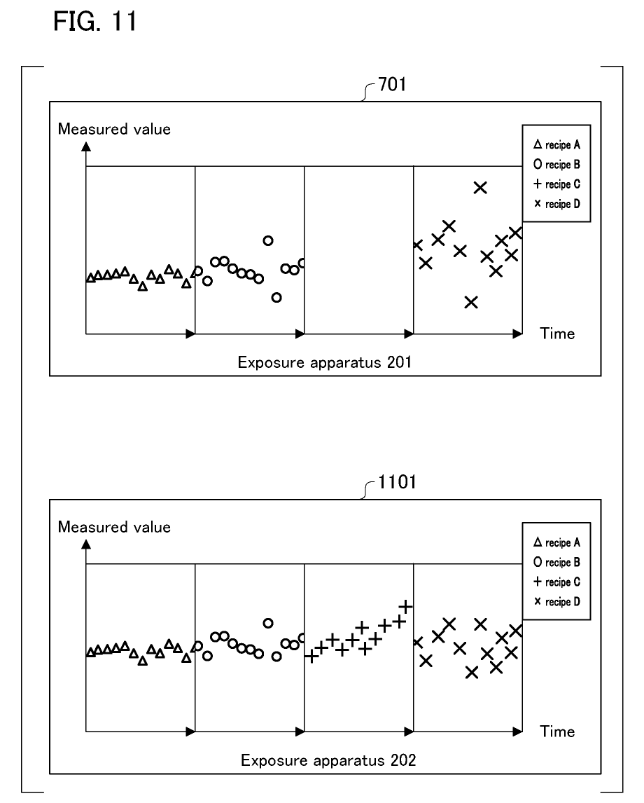

FIG. 11 is a diagram illustrating an example of a graph in which processing results of the exposure apparatus 201 illustrated in FIG. 1 and the exposure apparatus 202 are displayed in a time series for each processing condition (an upper stage represents the exposure apparatus 201, and a lower stage represents the exposure apparatus 202). As can be understood from FIG. 11, since the apparatuses are different from each other, trends of processing results differ even under the same processing condition. This is due to differences in characteristics of the apparatuses, differences in states of wafers that are processing targets, and the like.

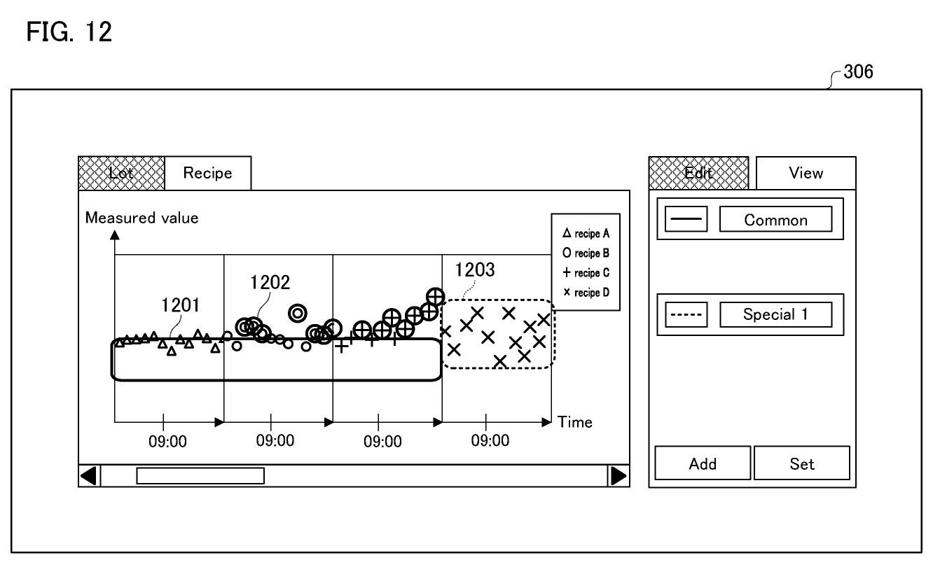

FIG. 12 is a diagram illustrating an example of a setting state for judging an abnormality on a graph in which processing results of the exposure apparatus 202 are displayed in a time series for each processing condition. Among the settings for judging an abnormality described in the first embodiment, when the common range 1201 is applied, processing results that are not necessarily abnormal for the exposure apparatus 202 such as processing results 1202 are judged as abnormal. Further, when the range 1203 set for judging an individual abnormality for each processing condition in the first embodiment is applied, the exposure apparatus 202 has a trend different from that of the exposure apparatus 201. For this reason, the results are not judged as abnormal, and for the exposure apparatus 202, there is no necessity to perform individual range settings for each processing condition.

On the other hand, as for the trend of recipe C in a graph 1101 of FIG. 11, it can be understood that the trend increases to the right and fluctuates over time. For a processing condition having a rightward increasing trend, there is a case in which management is performed in such a manner that whether an abnormality will occur is judged while grasping intermediate progress.

In this way, for the exposure apparatus 202, it is necessary to enable settings for judging an abnormality that is unique and different from apparatus-common settings set by the exposure apparatus 201.

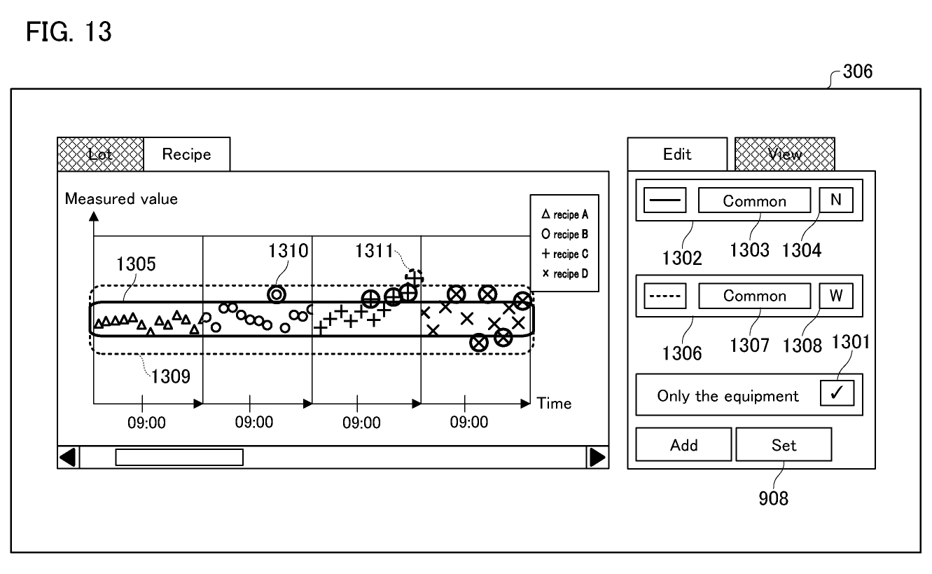

FIG. 13 is a diagram illustrating an example of a state in which a setting only for this apparatus, and normal and warning ranges within a range common to processing conditions, are set on a graph in which processing results of the exposure apparatus 202 are displayed in a time series for each processing condition. An only-this-apparatus setting 1301 is a check box indicating whether an apparatus to which the settings for judging an abnormality are applied is limited to this apparatus. When the only-this-apparatus setting 1301 is in a checked state, only the exposure apparatus 202, which is the apparatus currently displayed on the display device 306, becomes a target.

An item type level 1304 represents a level of an item type 1303 within an item 1302. The notation N (an initial of Normal) indicates being normal. Similarly, an item type level 1308 represents a level of an item type 1307 within an item 1306, and the notation W (an initial of Warning) indicates a warning and represents a level different from the item type level 1304. Since the item type 1303 and the item type 1307 represent the same item type, abnormality is judged for the same item at different levels. In other words, in FIG. 13, two levels of N and W are set for a common range item. In the present embodiment, although levels are represented using alphabets, the levels may be represented by numbers such as 1, 2, 3, … or by other characters or symbols.

As in the first embodiment, an item 1302 is selected and a range 1305 is set through a mouse operation, and an item 1306 is selected, and a range 1309 is set through a mouse operation. After the settings, display is performed as in the first embodiment such that it can be understood which range the processing result falls outside of, such as processing results 1310 and 1311.

When the reflect button 908 is pressed, a method for judging an abnormality is determined on the basis of the ranges set as the range 1305 and the range 1309, and since the check box of the only-this-apparatus setting 1301 is checked, the settings are stored in the storage device 304 as settings unique to the exposure apparatus 202. As a method for judging an abnormality, since the range 1305 is narrower than the range 1309, it is first checked whether the result falls within the range 1305 that is a narrower range, and if it does not, it is then checked whether the result falls within the range 1309. In other words, in the present embodiment, thresholds for judging an abnormality are set in multiple stages for each of the first group and the second group. Further, a screen on which the first group and the second group are selected also enables display (generation) for each processing apparatus.

If the check box of the only-this-apparatus setting 1301 is not checked, the ranges 1305 and 1309 become common settings also for other exposure apparatuses. In other words, the respective levels indicated by the item type levels 1304 and 1308 are also applicable in the first embodiment.

Further, it is also possible to set item type levels for individual ranges for each processing condition described in the first embodiment, and in a case in which individual ranges are set, the individual setting ranges are checked first.

After applying the settings for judging an abnormality, when measurement or exposure processing is performed by the exposure apparatus 202, and processing results are stored in the storage unit 402, it is checked that there is a setting for judging an abnormality of only the exposure apparatus 202, and a unique abnormality is judged. In a case in which an abnormality is judged, the judging results can be displayed on a screen and notified via a pop-up, an e-mail, a chat, or the like. The pop-up, the e-mail, the chat, or the like may be delivered only to a person managing the apparatus for which the settings for judging a unique abnormality have been performed.

According to the present embodiment, a user can perform settings for judging an abnormality unique to an apparatus without requiring advanced technical skills or a large amount of effort and time. Further, by notifying information indicating that a unique abnormality has been judged via a pop-up, an e-mail, a chat, or the like only to a supervisor of the apparatus for which the settings have been performed, information can be efficiently perceived.

Further, by enabling setting of item type levels, it is possible to visually understand whether a measurement or exposure processing result corresponds to a warning or an abnormality. If it is read that warnings continue and the trend is likely to lead to an abnormality, it becomes possible to take measures before an abnormality occurs, or to prepare to take immediate measures when an abnormality occurs.

Accordingly, by enabling measures to be taken before an abnormality occurs or to be taken immediately even if an abnormality occurs, an overall apparatus operation rate can be improved, which furthermore leads to improved profitability.

### Method of Manufacturing Article According to Embodiment

A method of manufacturing an article according to an embodiment of the present disclosure, for example, is appropriate for manufacturing articles such as microdevices including semiconductor devices and elements having fine structures. The method of manufacturing an article according to the present embodiment may include a forming step of forming a pattern of an original on a substrate using the above-described manufacturing system for an article and a processing step of processing the substrate on which the pattern has been formed in the forming step. Further, the method of manufacturing an article may include other well-known steps (oxidation, film formation, deposition, doping, planarization, etching, resist removal, dicing, bonding, packaging, and the like). The method of manufacturing an article according to the present embodiment is advantageous, as compared with conventional methods, in at least one of performance, quality, productivity, and production cost of an article.

While the present disclosure has described example embodiments, it is to be understood that some embodiments are not limited to the disclosed embodiments. The scope of the following claims is to be accorded the broadest interpretation so as to encompass all such modifications and equivalent structures and functions.

In addition, as a part or the whole of the control according to the embodiments, a computer program realizing the function of the embodiments described above may be supplied to the information processing apparatus and the like through a network or various storage media. Then, a computer (or a CPU, an MPU, or the like) of the information processing apparatus and the like may be configured to read and execute the program. In such a case, the program and the storage medium storing the program realize an embodiment of the present disclosure.

In addition, the present disclosure includes embodiments realized using at least one processor or circuit configured to perform functions of the embodiments explained above. For example, a plurality of processors may be used for distribution processing to perform functions of the embodiments explained above.

What is claimed is:

1. An information processing apparatus managing a processing apparatus that is a management target, the information processing apparatus comprising:
at least one processor; and
a memory coupled to the at least one processor, the memory storing instructions that, when executed by the at least one processor, cause the at least one processor to:
acquire processing results of the processing apparatus; and
generate a screen for selecting a first group and a second group used for judging an abnormality of the processing results on the basis of the acquired processing results together with a screen for displaying the processing results for each of a plurality of processing conditions.

2. The information processing apparatus according to claim 1, wherein the first group and the second group have different thresholds used for judging the abnormality.

3. The information processing apparatus according to claim 2, wherein the thresholds used for judging the abnormality are set in multiple stages for each of the first group and the second group.

4. The information processing apparatus according to claim 2, wherein, in the generation, a screen for displaying the thresholds used for judging the abnormality is generated.

5. The information processing apparatus according to claim 2, wherein the memory further stores instructions that, when executed by the at least one processor, cause the at least one processor to: specify an abnormality in the processing results of the processing apparatus using a threshold based on the first group and a threshold based on the second group.

6. The information processing apparatus according to claim 5, further comprising a display unit that displays the abnormality.

7. The information processing apparatus according to claim 2, wherein, at the time of the generation, processing results exceeding the threshold based on the first group and the threshold based on the second group are displayed with emphasis on a screen for displaying the processing results.

8. The information processing apparatus according to claim 1, wherein processing results acquired on the basis of a new processing condition after the first group and the second group are selected are handled as the first group.

9. The information processing apparatus according to claim 1,
wherein the processing apparatus is a pattern forming apparatus, and
wherein the processing results include results acquired by statistical calculation for each of a substrate on which the pattern forming apparatus forms a pattern, a pattern forming region on the substrate, and an original for forming the pattern on the substrate.

10. The information processing apparatus according to claim 1, wherein the screen for selecting the first group and the second group is able to be generated for each processing apparatus.

11. The information processing apparatus according to claim 1, wherein the screen for displaying the processing results for each of the plurality of processing conditions is able to be displayed with being switchable between a mode in which the plurality of processing conditions are collectively displayed in a time series and a mode in which the plurality of processing conditions are displayed in a time series for each processing condition.

12. An information processing apparatus managing a processing apparatus that is a management target, the information processing apparatus comprising:
at least one processor; and
a memory coupled to the at least one processor, the memory storing instructions that, when executed by the at least one processor, cause the at least one processor to:
acquire processing results of the processing apparatus;
output information for displaying the processing results for each of the plurality of processing conditions on the basis of the acquired processing results;
input a first group and a second group selected for judging an abnormality of the processing results; and
define thresholds for judging the abnormality on the basis of the first group and the second group that have been input and specify the abnormality in the processing results on the basis of the thresholds.

13. An information processing method executed by an information processing apparatus managing a processing apparatus that is a management target, the information processing method comprising:
acquiring processing results of the processing apparatus; and
generating a screen for selecting a first group and a second group used for judging an abnormality of the processing results on the basis of the acquired processing results together with a screen for displaying the processing results for each of a plurality of processing conditions.

14. A lithography apparatus that is managed by the information processing apparatus according to claim 1, the lithography apparatus comprising a forming unit configured to form a pattern for lithography.

15. A method of manufacturing an item, the method comprising:
forming a pattern on a substrate using the manufacturing system according to claim 14;
processing the substrate on which the pattern is formed through the formation; and
manufacturing an item from the substrate processed through the processing.
